(19) United States
(12) Patent Application Publication
(10) Pub. No.: US 2024/0315067 A1
(43) Pub. Date: Sep. 19, 2024

(54) Quantum Dot Light-Emitting Device and Method for Manufacturing Same, and Display Apparatus

(71) Applicants: Beijing BOE Technology Development Co., Ltd., Beijing (CN); BOE Technology Group Co., Ltd., Beijing (CN)

(72) Inventor: Zhigao LU, Beijing (CN)

(21) Appl. No.: 18/273,263

(22) PCT Filed: Jul. 18, 2022
(86) PCT No.: PCT/CN2022/106233

§ 371 Date: Jul. 19, 2023

(30) Foreign Application Priority Data
Jul. 26, 2021 (CN) 202110846230.X

(51) Int. Cl. H10K 50/17; H10K 50/115; H10K 71/12

(52) U.S. Cl. CPC H10K 50/17; H10K 50/115; H10K 71/12

(57) ABSTRACT

Provided are a quantum dot light-emitting device and a method for manufacturing same, and a display apparatus. The quantum dot light-emitting device includes: a quantum dot light-emitting layer and a hole injection layer, which is arranged on one side of the quantum dot light-emitting layer, wherein the quantum dot light-emitting layer includes a first surface close to one side of the hole injection layer, a passivation function layer is arranged on the first surface, and the passivation function layer is configured to modify the first surface.

### CROSS-REFERENCE TO RELATED APPLICATIONS

The present application is a U.S. National Phase Entry of International Application PCT/CN2022/106233 having an international filing date of Jul. 18, 2022, which claims priority of Chinese Patent Application No. 202110846230.X filed to the CNIPA on Jul. 26, 2021 and entitled “Quantum Dot Light-Emitting Device and Method for Manufacturing Same, and Display Apparatus”, the contents of the above-identified applications should be construed as being incorporated herein by reference.

### TECHNICAL FIELD

Embodiments of the present disclosure relate to, but is not limited to, the field of display technology, and particularly, to a quantum dot light-emitting device, a method for manufacturing the quantum dot light-emitting device, and a display apparatus.

### BACKGROUND

Quantum dots, also referred to as semiconductor nanocrystals, are a zero-dimension nanostructure composed of a small number of atoms and with typical three dimensions of 1 nm-100 nm. Quantum dots have narrow emission spectrum with adjustable band gap, and have been widely used in LED (Light-Emitting Diode) devices in recent years. A quantum dots light-emitting diode has advantages of self-luminescence, high color purity, low energy consumption, stable image, wide range of viewing angle and rich colors, etc. In recent years, they have been considered as a new generation of display technology following LCD and OLED (Organic Light-Emitting Diodes), and have broad application prospects.

Quantum Dot Light-Emitting Diode (QLED) is a device with quantum dots as a light-emitting layer. By introducing a light-emitting layer formed by quantum dots between different conductive materials, light with required wavelength can be obtained. The QLED has advantages of high color gamut, self-luminescence, low startup voltage and fast response speed, etc., which enable it to have broad application prospects in the fields of display and illumination, and to be a hot research direction at present.

### SUMMARY

The following is a summary of subject matters described in the present disclosure in detail. The summary is not intended to limit the protection scope of claims.

In a first aspect, an embodiment of the present disclosure provides a quantum dot light-emitting device, including: a quantum dot emitting layer and a hole injecting layer arranged on a side of the quantum dot emitting layer. The quantum dot emitting layer includes a first surface on a side close to the hole injecting layer, a passivation functional layer is arranged on the first surface, and the passivation functional layer is configured to modify the first surface.

In an exemplary implementation, the passivation functional layer at least includes passivation ions configured to be combined with the first surface to passivate the first surface.

In an exemplary implementation, the passivation functional layer further includes metal ions. The hole injecting layer includes a second surface on a side close to the quantum dot emitting layer, and the metal ions are arranged on a side of the second surface.

In an exemplary implementation, the metal ions are closer to the hole injecting layer than the passivation ions; and/or, the passivation ions are closer to the quantum dot emitting layer than the metal ions.

In an exemplary implementation, the passivation ions are halide ions.

In an exemplary implementation, a hole transporting layer is also included, which is located between the quantum dot emitting layer and the hole injecting layer, and at least a part of which is doped together with at least a part of the passivation functional layer.

In an exemplary implementation, a doping ratio of the hole transporting layer to the passivation functional layer is 1:1 to 20:1.

In an exemplary implementation, a thickness of the passivation functional layer is 1 nm-20 nm.

In an exemplary implementation, a first electrode and a second electrode are also included. The first electrode is located on a side of the hole injecting layer away from the quantum dot emitting layer, and the second electrode is located on a side of the quantum dot emitting layer away from the hole injecting layer.

In a second aspect, an embodiment of the present disclosure further provides a display apparatus, including the quantum dot light-emitting device described above.

In a third aspect, an embodiment of the present disclosure further provides a method for manufacturing a quantum dot light-emitting device, including:
forming a quantum dot emitting layer;
forming a passivation functional layer on a first surface of the quantum dot emitting layer, the passivation functional layer being configured to modify the first surface; and
forming a hole injecting layer on a side of the passivation functional layer away from the quantum dot emitting layer.

In an exemplary implementation, forming the passivation functional layer on the first surface of the quantum dot emitting layer includes:
forming the passivation functional layer from a metal halide on the first surface of the quantum dot emitting layer through an evaporation process.

In an exemplary implementation, forming the passivation functional layer on the first surface of the quantum dot emitting layer includes:
forming the passivation functional layer from a metal halide on the first surface of the quantum dot emitting layer through a same evaporation process, so that a hole transporting material forms the hole transporting layer, and at least a part of the passivation functional layer is doped together with at least a part of the hole transporting layer.

Other aspects may be understood upon reading and understanding the drawings and detailed description.

### DESCRIPTION OF DRAWINGS

FIG. 1 is a first schematic diagram of a structure of a quantum dot light-emitting device according to an embodiment of the present disclosure.

FIG. 2 is a first schematic diagram of a structure of a quantum dot light-emitting device according to an embodiment of the present disclosure after being electrified.

FIG. 3 is a schematic diagram of a structure after passivation ions are combined with a first surface in a quantum dot light-emitting device according to an embodiment of the present disclosure.

FIG. 4 is a second schematic diagram of a structure of a quantum dot light-emitting device according to an embodiment of the present disclosure;

FIG. 5 is a second schematic diagram of a structure of a quantum dot light-emitting device according to an embodiment of the present disclosure after being electrified.

FIG. 6 is a line chart of current density versus voltage of a quantum dot light-emitting device according to an embodiment of the present disclosure.

FIG. 7 is a third schematic diagram of a structure of a quantum dot light-emitting device according to an embodiment of the present disclosure.

FIG. 8 is a fourth schematic diagram of a structure of a quantum dot light-emitting device according to an embodiment of the present disclosure.

### DETAILED DESCRIPTION

Embodiments of the present disclosure will be described in detail below with reference to drawings. It is to be noted that implementations may be practiced in a plurality of different forms. Those of ordinary skills in the art may easily understand such a fact that embodiments and contents may be transformed into various forms without departing from the purpose and scope of the present disclosure. Therefore, the present disclosure should not be explained as being limited to contents described in following implementations only. The embodiments in the present disclosure and features in the embodiments may be combined randomly with each other if there is no conflict.

In the specification, for convenience, wordings indicating orientation or positional relationships, such as “middle”, “upper”, “lower”, “front”, “back”, “vertical”, “horizontal”, “top”, “bottom”, “inside”, and “outside”, are used for illustrating positional relationships between constituent elements with reference to the drawings, and are merely for facilitating the description of the specification and simplifying the description, rather than indicating or implying that a referred apparatus or element must have a particular orientation and be constructed and operated in the particular orientation. Therefore, they cannot be understood as limitations on the present disclosure. The positional relationships between the constituent elements may be changed as appropriate according to directions for describing the various constituent elements. Therefore, appropriate replacements may be made according to situations without being limited to the wordings described in the specification.

In the specification, unless otherwise specified and defined explicitly, terms “mount”, “mutually connect”, and “connect” should be understood in a broad sense. For example, a connection may be a fixed connection, or a detachable connection, or an integrated connection. It may be a mechanical connection or an electrical connection. It may be a direct mutual connection, or an indirect connection through middleware, or internal communication between two components. Those of ordinary skills in the art may understand meanings of the above-mentioned terms in the present disclosure according to situations.

In the present disclosure, “about” refers to that a boundary is defined not so strictly and numerical values within process and measurement error ranges are allowed.

Through the research of the inventor of the present disclosure, it is found that the contact interface between a quantum dot emitting layer and another functional layer is one of the factors affecting the performance of a quantum dot device, which is mainly shown in that a functional layer material quenches quantum dots, or does not match with quantum dot materials, such as mismatch of energy levels, mismatch of mobility, etc.

In related technologies, methods for improving the stability of quantum dot materials include changing core-shell structure of quantum dots, introducing new quantum dot ligands, etc. Improving hole injection capability includes selecting hole transporting materials with matched energy levels. However, there are some problems with these methods, for example, modification engineering for quantum dots has a high complexity, and poor process controllability, and there are only few hole transporting materials with matched quantum dot energy levels, etc.

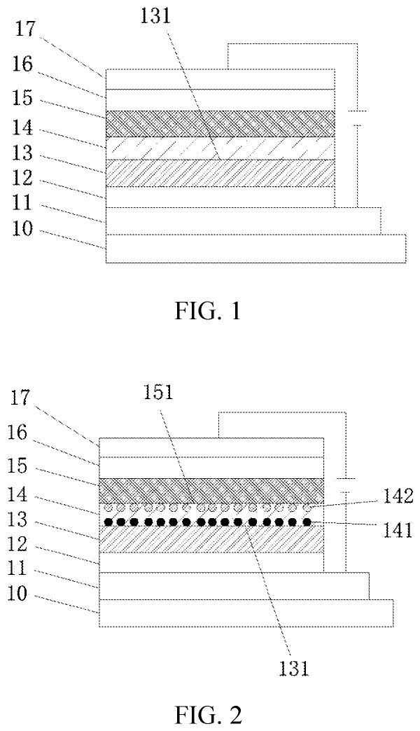

FIG. 1 is a schematic diagram of a structure of a quantum dot light-emitting device according to an embodiment of the present disclosure. As shown in FIG. 1, the quantum dot light-emitting device according to the embodiment of the present disclosure includes a substrate 10, a second electrode 11, an electron transporting layer (ETL) 12, a quantum dot emitting layer (QD EML) 13, a passivation functional layer 14, a hole transporting layer (HTL) 15, a hole injecting layer (HIL) 16, and a first electrode 17, which are sequentially stacked. In the quantum dot light-emitting device, the first electrode 17 is an anode and the second electrode 11 is a cathode. A thickness of the hole transporting layer 15 may be 5 nm to 50 nm, a thickness of the hole injecting layer 16 may be 5 nm to 50 nm, a thickness of the quantum dot emitting layer 13 may be 10 nm to 60 nm, and a thickness of the passivation functional layer 14 is 1 nm to 20 nm.

In an exemplary implementation, the quantum dot emitting layer 13 includes a first surface 131 on a side close to the hole injecting layer 16, the passivation functional layer 14 is arranged on the first surface 131, and a surface of the passivation functional layer 14 close to the quantum dot emitting layer 13 is at least partially contacted with the first surface 131. When the quantum dot light-emitting device according to the embodiment of the present disclosure is electrified and emits light, the passivation functional layer 14 is configured to modify the first surface 131, passivate defects of the first surface 131, and stabilize the quantum dot emitting layer 13.

FIG. 2 is a first schematic diagram of a structure of a quantum dot light-emitting device according to an embodiment of the present disclosure after being electrified. In an exemplary implementation, as shown in FIG. 2, the passivation functional layer 14 at least includes passivation ions 141. The passivation ions 141 are configured to be combined with the first surface 131 of the quantum dot emitting layer 13 to passivate defects on the first surface 131 of the quantum dot emitting layer 13. When the quantum dot light-emitting device according to the embodiment of the present disclosure is electrified and emits light, the passivation ions 141 are combined with the first surface 131 of the quantum dot emitting layer 13 under the action of an electric field, so as to passivate defects of the first surface 131 of the quantum dot emitting layer 13, which significantly improves thermal stability of the passivated quantum dot emitting layer 13. Compared with a quantum dot light-emitting device without passivation, the temperature tolerance of the quantum dot light-emitting device according to the embodiment of the present disclosure is improved by 20 Celsius degrees.

In an exemplary implementation, the passivation ions 141 can be combined with the first surface 131 of the quantum dot emitting layer 13 through dangling bonds on the quantum dots of the first surface 131; and/or, the passivation ions 141 can be adsorbed on the quantum dots of the first surface 131 of the quantum dot emitting layer 13; and/or, the passivation ions 141 can enter a shallow surface layer inside the quantum dot emitting layer 13 close to the hole injecting layer 16 and be combined with the first surface 131 of the quantum dot emitting layer 13.

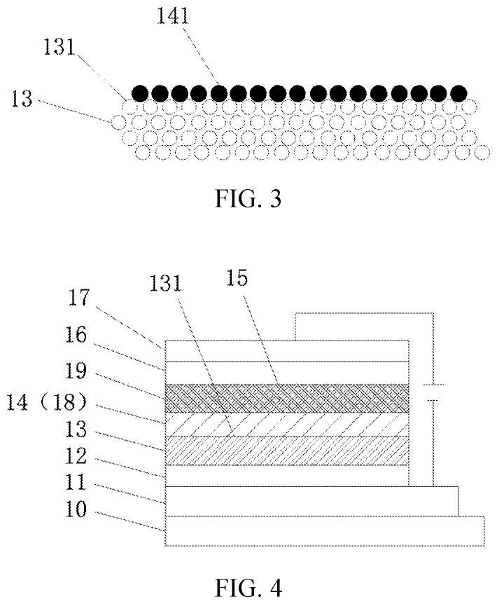

FIG. 3 is a schematic diagram of a structure of a quantum dot light-emitting device according to an embodiment of the present disclosure after passivation ions are combined with the first surface. In an exemplary implementation as shown in FIG. 3, the passivation ions 141 being chloride ions are taken as an example. When the quantum dot light-emitting device according to the embodiment of the present disclosure is electrified and emits light, the passivation ions 141 are combined with the quantum dots on the first surface 131 of the quantum dot emitting layer 13 under the action of an electric field. The passivation ions 141 can better passivate the defects on the first surface 131 than long-chain ligands such as oleic acid, etc. on the surface of quantum dots.

In an exemplary implementation, as shown in FIG. 2, the passivation functional layer 14 further includes metal ions 142 and the hole injecting layer 16 includes a second surface 151 on a side close to the quantum dot emitting layer 13. When the quantum dot light-emitting device according to the embodiment of the present disclosure is electrified and emits light, metal ions 142 move to the second surface 151 of the hole injecting layer 16 under the action of an electric field, and the metal ions 142 are arranged on a side of the second surface 151 of the hole transporting layer 15. Since a carrier mobility of the metal ions 142 is higher than that of the hole injecting layer 16, interfacial property of the quantum dot emitting layer 13 and the hole injecting layer 16 is improved, and the hole injecting and transporting rates of the quantum dot light-emitting device is enhanced.

In an exemplary implementation, when the quantum dot light-emitting device according to the embodiment of the present disclosure is electrified and emits light, the metal ions 142 in the passivation functional layer 14 are closer to the hole injecting layer 16 than the passivation ions 141, such that more metal ions 142 can be arranged on the side of the second surface 151 of the hole transporting layer 15; and/or, the passivation ions 141 in the passivation functional layer 14 are closer to the quantum dot emitting layer 13 than the metal ions 142, such that more passivation ions 141 can be combined with the quantum dots on the first surface 131 of the quantum dot emitting layer 13.

In an exemplary implementation, a material of the passivation functional layer 14 may be a metal halide, for example, the material of the passivation functional layer 14 may be ferric chloride, zinc chloride, etc. The passivation ions 141 in the passivation functional layer 14 may be halide ions, for example, the passivation ions 141 may be fluorine ions, chloride ions, bromine ions, iodine ions, astatine ions, etc. The metal ions 142 in the passivation functional layer 14 may be iron ions, zinc ions, aluminum ions, etc. After the halide ions are combined with the first surface 131 of the quantum dot emitting layer 13, the defects of the first surface 131 of the quantum dot emitting layer 13 are passivated, such that the quantum dot emitting layer 13 is more stable. The metal ions 142 are arranged on the side of the second surface 151 of the hole transporting layer 15, to modify the second surface 151 of the hole transporting layer 15, so that the interfacial property between the quantum dot emitting layer 13 and the hole transporting layer 15 is improved, and the capability of injecting holes into the quantum dot emitting layer 13 is enhanced.

In an exemplary implementation, the quantum dot emitting layer 13 are combined with the passivation ions 141 only on a surface away from the electron transporting layer 12 and close to the passivation functional layer 14, such that a hole injection performance of the surface of the quantum dot emitting layer 13 close to the hole injecting layer 16 can be selectively improved.

In an exemplary implementation, the quantum dot light-emitting device according to the embodiment of the present disclosure may be a top-emission device, the first electrode 17 is a transparent conductive electrode, and the transparent conductive electrode may be a metal nanowire, indium tin oxide (ITO), thin silver, thin aluminum, etc. Alternatively, the quantum dot light-emitting device according to the embodiment of the present disclosure may be bottom-emission device. The second electrode 11 is a transparent conductive electrode which may be a metal nanowire, indium tin oxide (ITO), thin silver, thin aluminumetc.

In the quantum dot light-emitting device according to the embodiment of the present disclosure, the electron transporting layer 12 receives electrons from the cathode and can transfer the supplied electrons to the quantum dot emitting layer. The electron transporting layer 12 is also used for facilitating transporting the electrons. A material of the electron transporting layer 12 may be azo compound nanoparticles (AZO-NPs), zinc magnesium oxide alloy nanoparticles (ZMO-NPs), zinc oxide nanoparticles (ZnO-NPs), sputtered zinc oxide non-nanoparticles, and zinc aluminum oxide alloy nanoparticles. However, the exemplary implementations of the present application are not limited thereto.

In the quantum dot light-emitting device according to the embodiment of the present disclosure, the quantum dot emitting layer 13 is used for emitting light. A material of the quantum dot emitting layer 13 may be selected from, but not limited to, binary phase quantum dots, ternary phase quantum dots, or quaternary phase quantum dots, etc. As an example, the binary phase quantum dots selected from, but not limited to, CdS, CdSe, CdTe, InP, AgS, PbS, PbSe, or HgS, etc. The ternary phase quantum dots are selected from, but not limited to, ZnCdS, CuInS, ZnCdSe, ZnSeS, ZnCdTe, or PbSeS, etc. The quaternary phase quantum dots are selected from, but not limited to, ZnCdS/ZnSe, CulnS/ZnS, ZnCdSe/ZnS, CuInSeS or ZnCdTe/ZnS, PbSeS/ZnS, etc.

In the quantum dot light-emitting device according to the embodiment of the present disclosure, the hole transporting layer 15 may play a role of facilitating hole transport. A material of the hole transporting layer 15 may be selected from an organic material with hole transport capability, which includes but is not limited to one or more of poly(9,9-dioctylfluorene-CO—N-(4-butylphenyl) diphenylamine) (TFB), polyvinylcarbazole (PVK), poly(N,N′-bis(4-butylphenyl)-N,N′-bis(phenyl) benzidine) (poly-TPD), poly(9,9-dioctylfluorene-co-bis-N,N-phenyl-1,4-phenylenediamine) (PFB), 4,4′,4″-tris(carbazol-9-yl) triphenylamine (TCTA), 4,4′-bis(9-carbazole) biphenyl (CBP), N,N′-diphenyl-N,N′-bis(3-methylphenyl)-1,1′-biphenyl-4,4′-diamine (TPD), N,N′-diphenyl-N,N′-(1-naphthyl)-1,1′-biphenyl-4,4′-diamine (NPB), doped graphene, undoped graphene, and C60. The hole transporting layer 15 may also be selected from an inorganic material with hole transport capability, which includes but is not limited to one or more of doped or undoped MoOx, VOx, WOx, CrOx, CuO, MoS2, MoSe2, WS2, WSe2, and CuS, but the exemplary implementations of the present application are not limited thereto.

In the quantum dot light-emitting device according to the embodiment of the present disclosure, the hole injecting layer 16 may facilitate the injection of holes. A material of the hole injecting layer 16 include, but are not limited to, one or more of poly(3,4-ethylene dioxythiophene)-polystyrene sulfonic acid (PEDOT: PSS), copper phthalocyanine (CuPc), 2,3,5,6-tetrafluoro-7,7′,8,8′-tetracyanoquinone-dimethane (F4-TCNQ), 2,3,6,7,10,11-hexocyano-1,4,5,8,9,12-hexaazabenzophenanthrene (HATCN), poly(perfluoroethylene-perfluoroethersulfonic acid) (PFFSA)-doped polythiophenothiophene (PTT), transition metal oxides, and metal chalcogenides. Preferably, the transition metal oxides include one or more of MoO3, VO2, WO3, CrO3, and CuO, and the metal chalcogenides include one or more of MoS2, MoSe2, WS2, WSe2, and CuS, but the exemplary implementations of the present application are not limited thereto.

In the quantum dot light-emitting device according to the embodiment of the present disclosure, the first electrode 17 is an anode, and the first electrode 17 includes an oxide material, a metal material, or an oxide-metal composite material. For example, the oxide material includes, but is not limited to, at least one or more of indium tin oxide (ITO), indium zinc oxide (IZO), zinc oxide (ZnO), indium gallium oxide (IGO), gallium zinc oxide (GZO), indium gallium zinc oxide (IGZO), indium oxide (In2O3), aluminum zinc oxide (AZO), magnesium-doped zinc oxide (MZO), aluminum-doped magnesium oxide (AMO), antimony-doped tin oxide (ATO), fluorine-doped tin dioxide (FTO), fluorine-phosphorus co-doped tin dioxide (FPTO). However, the exemplary implementations of the present application are not limited thereto.

In the quantum dot light-emitting device according to the embodiment of the present disclosure, the second electrode 11 is a cathode, and the second electrode 11 includes an oxide material, a metal material, or an oxide-metal composite material. For example, the oxide material includes, but is not limited to, at least one or more of indium tin oxide (ITO), indium zinc oxide (IZO), zinc oxide (ZnO), indium gallium oxide (IGO), gallium zinc oxide (GZO), indium gallium zinc oxide (IGZO), indium oxide (In2O3), aluminum zinc oxide (AZO), magnesium-doped zinc oxide (MZO), aluminum-doped magnesium oxide (AMO), antimony-doped tin oxide (ATO), fluorine-doped tin dioxide (FTO), fluorine-phosphorus co-doped tin dioxide (FPTO). However, the exemplary implementations of the present application are not limited thereto.

As shown in FIG. 1, a manufacturing process of a quantum dot light-emitting device according to an embodiment of the present disclosure includes:
(1) A substrate material is coated on a glass carrier plate, and is cured to form a film to form a substrate 10. A second electrode 11 is then formed on the substrate 10. In an embodiment of the present disclosure, the substrate 10 may be a rigid substrate or a flexible substrate. The rigid substrate includes, but is not limited to, one or more of glass, metal foil, or ceramic material. The flexible substrate may be polyimide (PI), polyethylene terephthalate (PET), a surface-treated polymer soft film, or other materials.
(2) A thin film of electron transporting layer material with a thickness of 30 nm is spin-coated on the second electrode 11 through a spin-coating process, and then annealed at a temperature between 10° C. and 50° C., such that the thin film of electron transporting layer material forms an electron transporting layer 12. Here, a rotating speed of spin-coating is 1000 r/min-4000 r/min, and time of spin-coating is 10 seconds-50 seconds.
(3) A thin film of quantum dot emitting layer material with a thickness of 20 nm is spin-coated on the electron transporting layer 12 through a spin-coating process, and then annealed at a temperature between 100° C. and 200° C., such that the thin film of quantum dot emitting layer material forms a quantum dot emitting layer 13. Here, a rotating speed of spin-coating is 1000 r/min-5000 r/min.
(4) A passivation functional layer 14 with a thickness of 1 nm to 20 nm is formed on the first surface 131 of the quantum dot emitting layer 13 through an evaporation process. The passivation functional layer 14 may be made of a metal halide.
(5) A thin film of hole transporting material is spin-coated on the passivation functional layer 14 through a spin-coating process, and then annealed at a temperature between 80° C. and 200° C., such that the thin film of hole transporting material forms a hole transporting layer 15. Here, a rotating speed of spin-coating is 1000 r/min-5000 r/min.
(6) A thin film of hole injecting material is spin-coated on the hole transporting layer 15 through a spin-coating process, and then annealed at a temperature between 100° C. and 250° C. such that the thin film of hole injecting material forms a hole-injecting layer 16. Here, a rotating speed of spin-coating is 1000 r/min-5000 r/min.

As can be seen from the structure and the manufacturing process of the quantum dot light-emitting device according to the embodiment of the present disclosure, in the quantum dot light-emitting device provided by the embodiment of the present disclosure, the defects on the first surface 131 of the quantum dot emitting layer 13 are passivated by the passivation functional layer 14. The thermal stability of the passivated quantum dot emitting layer 13 is significantly improved. Furthermore, the second surface 151 of the hole transporting layer 15 is modified by the passivation functional layer 14, thereby improving the interfacial property between the quantum dot emitting layer 13 and the hole transporting layer 15 and enhancing the capability of injecting holes into the quantum dot emitting layer 13.

The manufacturing process of the quantum dot light-emitting device according to the embodiment of the present disclosure may be achieved by using existing mature manufacturing equipment, has little improvement on the existing process, is capable of being well compatible with the existing manufacturing process, and has advantages such as simple process implementation, high production efficiency, low production cost and high yield rate, thus having good application prospects.

FIG. 4 is a second schematic diagram of a structure of a quantum dot light-emitting device according to an embodiment of the present disclosure. In an exemplary implementation, as shown in FIG. 4, a hole transporting layer 15 is located between a quantum dot emitting layer 13 and a hole injecting layer 16, and at least a part of the hole transporting layer 15 is doped with at least a part of the passivation functional layer 14. For example, the passivation functional layer 14 and the hole transporting layer 15 are partially or completely doped together by a same evaporation process. In the embodiment of the present disclosure, by doping the passivation functional layer 14 and the hole transporting layer 15 together, a thickness of the quantum dot light-emitting device can be reduced, the production process can be simplified and the production efficiency can be improved.

In an exemplary implementation, as shown in FIG. 4, the hole transporting layer 15 includes a first sub-hole transporting layer 18 and a second sub-hole transporting layer 19, which are arranged by sequentially stacking. The first sub-hole transporting layer 18 is located on a side of the hole transporting layer 15 close to the quantum dot emitting layer 13, and the second sub-hole transporting layer 19 is located on a side of the hole transporting layer 15 away from the quantum dot emitting layer 13. The first sub-hole transporting layer 18 and the passivation functional layer 14 are doped together by a same evaporation process to form a doped film layer. A surface of the doped film layer close to the second sub-hole transporting layer 19 is at least partially in contact with the second sub-hole transporting layer 19. A surface of the doped film layer close to the side of the quantum dot emitting layer 13 is at least partially in contact with the quantum dot emitting layer 13.

In an exemplary implementation, a same hole transporting material, or different hole transporting materials, may be used for the first sub-hole transporting layer 18 and the second sub-hole transporting layer 19, which is not limited herein in the embodiments of the present disclosure.

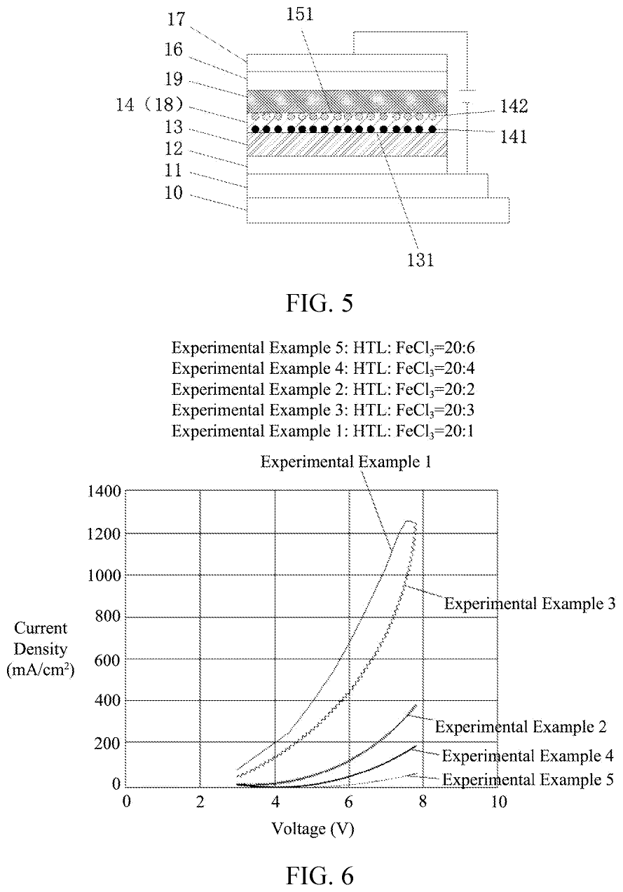

FIG. 5 is a second schematic diagram of a structure of a quantum dot light-emitting device according to an embodiment of the present disclosure after being electrified. In an exemplary implementation, as shown in FIG. 5, the passivation functional layer 14 includes passivation ions 141 and metal ions 142. When the quantum dot light-emitting device according to the embodiment of the present disclosure is electrified and emits light, in the doped film layer in which the hole transporting layer 15 and the passivation functional layer 14 are doped together, the passivation ions 141 move to the first surface 131 of the quantum dot emitting layer 13 under the action of an electric field. The passivation ions 141 are configured to be combined with the first surface 131 of the quantum dot emitting layer 13 to passivate defects on the first surface 131 of the quantum dot emitting layer 13. Thermal stability of the passivated quantum dot emitting layer 13 is significantly improved. The metal ions 142 move to the second surface 151 of the hole transporting layer 15 under the action of an electric field. The metal ions 142 are arranged on the side of the second surface 151 of the hole transporting layer 15, to modify the second surface 151 of the hole transporting layer 15, so that the interfacial property between the quantum dot emitting layer 13 and the hole transporting layer 15 is improved, and the capabilities of hole injection and transport of the quantum dot emitting layer 13 are enhanced.

In an exemplary implementation, in the doped film layer in which the hole transporting layer 15 and the passivation functional layer 14 are doped together, a doping ratio of the hole transporting layer 15 to the passivation functional layer 14 is 1:1 to 20:1. By adjusting the doping ratio of the hole transporting layer 15 to the passivation functional layer 14, the capabilities of hole injection and transport can be greatly improved.

FIG. 6 is a line chart of current density versus voltage of a quantum dot light-emitting device according to an embodiment of the present disclosure. The quantum dot light-emitting device includes a substrate 10, a second electrode 11, an electron transporting layer 12, a quantum dot emitting layer 13, a passivation functional layer 14, a hole transporting layer 15, a hole injecting layer 16, and a first electrode 17, which are sequentially stacked. In the quantum dot light-emitting device, the electron transporting layer 12 is made of zinc oxide nanoparticles (ZnO-NPs), and a thickness of the electron transporting layer 12 is 30 nm. The quantum dot emitting layer 13 is of CdS, and the thickness of the quantum dot emitting layer 13 is 20 nm; The passivation functional layer 14 is made of ferric chloride, and the hole transporting layer 15 is made of an organic material with hole transport capability. The hole transporting layer 15 includes a first sub-hole transporting layer 18 and a second sub-hole transporting layer 19 which are sequentially stacked. The first sub-hole transporting layer 18 is located on a side of the hole transporting layer 15 close to the quantum dot emitting layer 13, and the second sub-hole transporting layer 19 is located on a side of the hole transporting layer 15 away from the quantum dot emitting layer 13. The first sub-hole transporting layer 18 and the passivation functional layer 14 are doped together through a same evaporation process to form a doped film layer with a thickness of 20 nm. The hole injecting layer 16 is made of an organic material, and a thickness of the hole injecting layer 16 is 5 nm. In Experimental Example 1, a doping ratio of the hole transporting layer 15 (HTL) to the passivation functional layer 14 (FeCl₃) is 20:1 in the doped film layer. In Experimental Example 2, the doping ratio of the hole transporting layer 15 (HTL) to the passivation functional layer 14 (FeCl₃) is 20:2 in the doped film layer. In Experimental Example 3, the doping ratio of the hole transporting layer 15 (HTL) to the passivation functional layer 14 (FeCl₃) is 20:3 in the doped film layer. In Experimental Example 4, a doping ratio of the hole transporting layer 15 (HTL) to the passivation functional layer 14 (FeCl₃) is 20:4 in the doped film layer. In Experimental Example 5, a doping ratio of the hole transporting layer 15 (HTL) to the passivation functional layer 14 (FeCl₃) is 20:6 in the doped film layer. In Experimental Example 6, the passivation functional layer 14 (FeCl₃) is not doped in the doped film layer. Electrification experiments are conducted to the above-mentioned Experimental Examples 1 to 6, and the current densities of the quantum dot light-emitting device are measured under voltages of 2V to 8V in the above-mentioned Experimental Examples 1 to 6. The experimental results are shown in FIG. 6.

It can be seen from the experimental results that the current density of the quantum dot light-emitting device of Experimental Example 6 is about 10 mA/cm² under 5V. With the continuous decrease of the doping ratio of FeCl₃, the current densities of the quantum dot light-emitting device under the same voltages increase. This indicates that the doping of FeCl₃ can increase the current of the quantum dot light-emitting device under the same voltage, and reduce the interface voltage drop of the film layer. Under the same voltage, the increase of current indicates that more carriers are injected.

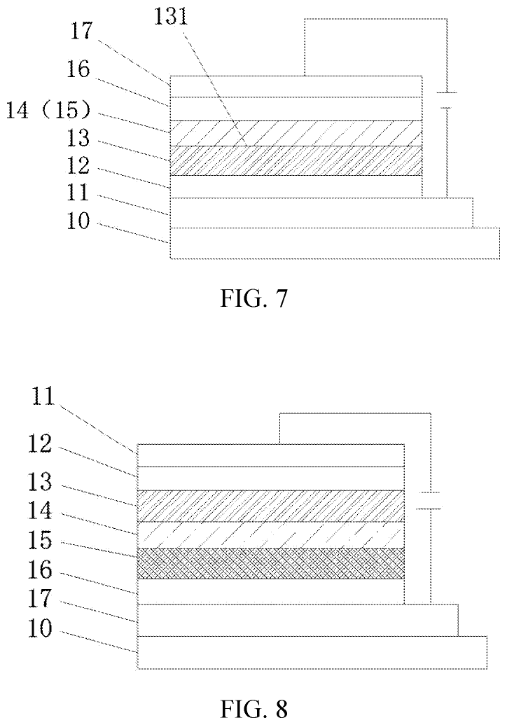

FIG. 7 is a third schematic diagram of a structure of a quantum dot light-emitting device according to an embodiment of the present disclosure. In an exemplary implementation, as shown in FIG. 7, the hole transporting layer 15 and the passivation functional layer 14 are doped together through a same evaporation process to form a doped film layer. A surface of the doped film layer close to the hole injecting layer 16 is at least partially in contact with the hole injecting layer 16. A surface of the doped film layer close to the quantum dot emitting layer 13 is at least partially in contact with the quantum dot emitting layer 13. In the embodiment of the present disclosure, by doping the passivation functional layer 14 and the hole transporting layer 15 together, the thickness of the quantum dot light-emitting device can be reduced, the production process can be simplified and the production efficiency can be improved.

FIG. 8 is a fourth schematic diagram of the structure of a quantum dot light-emitting device according to an embodiment of the present disclosure. In an exemplary implementation, as shown in FIG. 8, the quantum dot light-emitting device according to the embodiment of the present disclosure may be of an upright structure. The quantum dot light-emitting device according to the embodiment of the present disclosure includes a substrate 10, a second electrode 11, a hole injecting layer (HIL) 16, a hole transporting layer (HTL) 15, a passivation functional layer 14, a quantum dot emitting layer (QD EML) 13, an electron transporting layer (ETL) 12 and a first electrode 17, which are sequentially stacked.

An embodiment of the present disclosure further provides a display apparatus, including any one of the quantum dot light-emitting device described above. The display apparatus includes a mobile phone, a tablet computer, a wearable smart product (such as a smart watch, a bracelet, or the like), a personal digital assistant (PDA), a vehicle-mounted computer, or the like. A specific form of the above foldable display apparatus is not specially limited in the embodiments of the present application.

An embodiment of the present disclosure further provides a method for manufacturing a quantum dot light-emitting device, including:
forming a quantum dot emitting layer;
forming a passivation functional layer on a first surface of the quantum dot emitting layer, the passivation functional layer being configured to modify the first surface;
forming a hole injecting layer on a side of the passivation functional layer away from the quantum dot emitting layer.

In an exemplary implementation, forming the passivation functional layer on the first surface of the quantum dot emitting layer includes:
forming the passivation functional layer from a metal halide on the first surface of the quantum dot emitting layer through an evaporation process.

In an exemplary implementation, forming the passivation functional layer on the first surface of the quantum dot emitting layer includes:
forming the passivation functional layer from a metal halide on the first surface of the quantum dot emitting layer through a same evaporation process, so that a hole transporting material forms the hole transporting layer, and at least a part of the passivation functional layer and at least a part of the hole transporting layer are doped together.

With the method for manufacturing the quantum dot light-emitting device according to the embodiment of the present disclosure, the passivation functional layer can be formed on any surface of the quantum dot emitting layer through an evaporation process, thereby selectively improving the performance of the surface of the quantum dot emitting layer.

In the method for manufacturing the quantum dot light-emitting device according to the embodiment of the present disclosure, the passivation functional layer is formed through the evaporation process. Introduction of a solvent is not needed in the process of manufacturing the passivation functional layer, thereby avoiding the solvent from affecting morphology of the quantum dot emitting layer, and the thickness of the passivation functional layer introduced can be precisely controlled by the evaporation process, which brings good film forming property.

The drawings of the present disclosure only involve structures involved in the present disclosure, and other structures may refer to conventional designs. The embodiments of the present disclosure, i.e., features in the embodiments, may be combined with each other to obtain new embodiments if there is no conflict.

Those of ordinary skills in the art should understand that modifications or equivalent replacements may be made to the technical solutions of the present disclosure without departing from the spirit and scope of the technical solutions of the present disclosure, and shall all fall within the scope of the claims of the present disclosure.

1. A quantum dot light-emitting device, comprising: a quantum dot emitting layer and a hole injecting layer arranged on a side of the quantum dot emitting layer, wherein the quantum dot emitting layer comprises a first surface on a side close to the hole injecting layer, a passivation functional layer is arranged on the first surface, and the passivation functional layer is configured to modify the first surface.

2. The quantum dot light-emitting device according to claim 1, wherein the passivation functional layer at least comprises passivation ions configured to be combined with the first surface to passivate the first surface.

3. The quantum dot light-emitting device according to claim 2, wherein the passivation functional layer further comprises metal ions, the hole injecting layer comprises a second surface on a side close to the quantum dot emitting layer, and the metal ions are arranged on a side of the second surface.

4. The quantum dot light-emitting device according to claim 3, wherein the metal ions are closer to the hole injecting layer than the passivation ions; and/or, the passivation ions are closer to the quantum dot emitting layer than the metal ions.

5. The quantum dot light-emitting device according to claim 2, wherein the passivation ions are halide ions.

6. The quantum dot light-emitting device according to claim 1, further comprising a hole transporting layer located between the quantum dot emitting layer and the hole injecting layer, wherein at least a part of the hole transporting layer is doped together with at least a part of the passivation functional layer.

7. The quantum dot light-emitting device according to claim 6, wherein a doping ratio of the hole transporting layer to the passivation functional layer is 1:1 to 20:1.

8. The quantum dot light-emitting device according to claim 1, wherein a thickness of the passivation functional layer is 1 nm-20 nm.

9. The quantum dot light-emitting device according to claim 1, further comprising a first electrode and a second electrode, wherein the first electrode is located on a side of the hole injecting layer away from the quantum dot emitting layer, and the second electrode is located on a side of the quantum dot emitting layer away from the hole injecting layer.

10. A display apparatus, comprising the quantum dot light-emitting device according to claim 1.

11. A method for manufacturing a quantum dot light-emitting device, comprising:
forming a quantum dot emitting layer;
forming a passivation functional layer on a first surface of the quantum dot emitting layer, the passivation functional layer being configured to modify the first surface; and
forming a hole injecting layer on a side of the passivation functional layer away from the quantum dot emitting layer.

12. The method for manufacturing the quantum dot light-emitting device according to claim 11, wherein forming the passivation functional layer on the first surface of the quantum dot emitting layer comprises:
forming the passivation functional layer from a metal halide on the first surface of the quantum dot emitting layer through an evaporation process.

13. The method for manufacturing the quantum dot light-emitting device according to claim 11, wherein forming a passivation functional layer on a first surface of the quantum dot emitting layer comprises:
forming the passivation functional layer from a metal halide on the first surface of the quantum dot emitting layer through a same evaporation process, so that a hole transporting material forms the hole transporting layer, and at least a part of the passivation functional layer is doped together with at least a part of the hole transporting layer.

14. The quantum dot light-emitting device according to claim 2, wherein a thickness of the passivation functional layer is 1 nm-20 nm.

15. The quantum dot light-emitting device according to claim 3, wherein a thickness of the passivation functional layer is 1 nm-20 nm.

16. The quantum dot light-emitting device according to claim 4, wherein a thickness of the passivation functional layer is 1 nm-20 nm.

17. The quantum dot light-emitting device according to claim 5, wherein a thickness of the passivation functional layer is 1 nm-20 nm.

18. The quantum dot light-emitting device according to claim 6, wherein a thickness of the passivation functional layer is 1 nm-20 nm.

19. The quantum dot light-emitting device according to claim 7, wherein a thickness of the passivation functional layer is 1 nm-20 nm.

20. The quantum dot light-emitting device according to claim 2, further comprising a first electrode and a second electrode, wherein the first electrode is located on a side of the hole injecting layer away from the quantum dot emitting layer, and the second electrode is located on a side of the quantum dot emitting layer away from the hole injecting layer.
